(19) United States
(12) Patent Application Publication
(10) Pub. No.: US 2024/0393184 A1
(43) Pub. Date: Nov. 28, 2024

(54) THIN COMPACT THERMOCOUPLE AND METHOD FOR MANUFACTURING SUCH A THERMOCOUPLE

(71) Applicant: SAFRAN, PARIS (FR)

(72) Inventors: Maya GEAGEA, MOISSY-CRAMAYEL (FR); Ioannis Jean-Marc STASINOPOULOS, MOISSY-CRAMAYEL (FR)

(73) Assignee: SAFRAN, PARIS (FR)

(21) Appl. No.: 18/692,098

(22) PCT Filed: Sep. 29, 2022
(86) PCT No.: PCT/FR2022/051839

§ 371 Date: Mar. 14, 2024

(30) Foreign Application Priority Data
Sep. 29, 2021 (FR) FR2110277

(51) Int. Cl. G01K 7/02; G01K 1/14; H10N 10/01; H10N 10/13; H10N 10/17

(52) U.S. Cl. CPC G01K 7/02; G01K 1/14; H10N 10/01; H10N 10/13; H10N 10/17

(57) ABSTRACT

The invention relates to a thermocouple comprising: —a substrate comprising an upper surface; —a first arm comprising a first horizontal part and a first connection terminal; —a second arm comprising a second horizontal part and a second connection terminal; the first arm being arranged on the upper surface of the substrate, the second arm being arranged on the first arm such that the second horizontal part at least partially covers the first horizontal part and such that the second connection terminal is in contact with the upper part of the substrate, a hot junction of the thermocouple being defined by the zone of contact between the first arm and the second arm.

### TECHNICAL FIELD

The invention relates to a printed thermocouple as well as the manufacturing method thereof and finds application in particular in aeronautics for measuring temperatures in confined parts of aeronautical equipment, in particular engines.

It also finds application in the field of microelectronics to probe the temperature of an integrated circuit chip in order to optimize its cooling, monitor its performance and avoid damage by overheating. The positioning of the measurement point must be very precise and the size of the measurement point very small, given the very small size of the chip.

### STATE OF THE ART

Thermocouples are probes used for measuring temperature. These temperature probes have a wide field of industrial and scientific applications for the temperature range which varies from very cold temperatures (for example around −270° C.) to very hot temperatures (for example around 2300° C.). Such thermocouples are for example used in aeronautics.

The typical design of a thermocouple consists of two conductive metal materials of different natures, that is to say with different thermal and electrical properties. The two metals are in contact at one end forming a “hot junction”. This hot junction represents the point where the measurement is taken.

In most applications today wired thermocouples are used. The hot junction then simply represents a solder of the two wires. However, wired thermocouples are bulky and disrupt the flow in aeronautical equipment, particularly when they are integrated into an aircraft engine in contact with the flow circulating in the engine, the performance of the engine being degraded as well as the environment to be probed.

To improve the integration of thermocouples, more recently thin thermocouples have been developed and have a two-dimensional geometry (that is to say with a small thickness of the order of a few hundred nanometers to a few tens of micrometers). These thin thermocouples are easier to integrate. They are compatible with nano and micro fabrication or deposition methods, implemented in the electronics and aeronautical industries, respectively.

Thus they allow to design components integrating measurement functions—and therefore health monitoring—from manufacturing.

In these thin thermocouples the hot junction is materialized by the superposition of depositions of different layers, is connected to connection terminals by the arms of the thermocouple, the whole remaining almost two-dimensional, the connection terminals being connected to what is called the “cold junction”. Indeed, the operating principle of the thermocouple is based on the Seebeck effect. This effect indicates that when a temperature gradient appears between the hot junction and the cold junction of the thermocouple, this generates a thermoelectric voltage. This voltage thus measured allows to obtain the temperature at the hot junction.

A problem with thin thermocouple architectures is that they are still too bulky and take up a large surface area.

### DISCLOSURE OF THE INVENTION

The invention proposes to reduce the bulk of a thermocouple.

To this end, the invention proposes a thermocouple comprising: a substrate comprising an upper surface; a first arm comprising a first horizontal part and a first connection terminal; a second arm comprising a second horizontal part and a second connection terminal; the first arm being arranged on the upper surface of the substrate, the second arm being arranged on the first arm such that the second horizontal part at least partially overlaps the first horizontal part and such that the second connection terminal is in contact with the upper part of the substrate, a hot junction of the thermocouple being defined by the zone of contact between the first arm and the second arm.

The invention is advantageously supplemented by the following features, taken alone or in any of their technically possible combinations:
the first horizontal part of the first arm completely overlaps the second horizontal part of the second arm;
the first horizontal part of the first arm partially overlaps the second horizontal part of the second arm so as to define a first free space between the substrate, the first arm and the second arm, a dielectric material being, preferably, arranged in the first space free;
the first arm comprises an internal end and an external end from which the first connection terminal extends from the substrate;
the second arm comprises an internal end and an external end from which the second connection terminal extends;
the first arm partially overlaps the second arm so as to define a second free space between the first connection terminal and the internal end of the second arm;
the thermocouple comprises a dielectric material arranged in the second free space;
the dielectric material is such that it is insulating in a temperature operating range of said thermocouple;
the second free space has a larger volume than the volume of the first free space;
the substrate is electrically insulating and preferably selected from the following group: a thermal barrier coating made of yttria zirconia, yttrium or ytterbium mono- or disilicate, alumina, oxide layer of a superalloy, or any other dielectric;
the first arm and the second arm are enveloped in an insulating material of the same material as the substrate.

The invention also relates to a method for manufacturing a thermocouple according to the invention, the method comprising the following steps:
depositing the first arm on a substrate;
depositing the second connection terminal of the second arm on the substrate so as to optionally leave a first free space between the first arm and the second arm;
depositing a horizontal part of the second arm from the second connection terminal towards the inside of the substrate so as to at least partially overlap the first arm to form a hot junction of the thermocouple.

The invention also relates to a device for measuring the temperature of a turbomachine blade, comprising a thermocouple according to the invention, the substrate being arranged on the blade.

The invention also relates to a device for measuring the temperature of a determined zone of an electronic circuit, comprising a thermocouple according to the invention, the thermocouple being arranged in the determined zone such that the hot junction is arranged on the determined zone.

Unlike known structures, the invention uses a three-dimensional superposition and not a simple arrangement in a plane which, unlike known architectures, consider the thermocouple as a point junction of two different materials, and interconnection wires or tracks: the elements of the thermocouple are arranged both in the plane and out of the plane of the substrate.

The structure proposed for the thermocouple is compact by stacking the arms of the thermocouple by bringing together the interconnection zones to be more compact. However, the interconnection zones can be spaced as desired in relation to the hot junction, the latter being however compact.

Furthermore, the thermocouple of the invention is more solid. Indeed, in the case of the classic architecture of thermocouples, the two metals only intersect at a very limited location and makes the hot junction vulnerable to damage (erosion, shocks, etc.).

The invention allows to reduce the surface occupied by the thermocouple. The thermocouple ensures both a minimum occupied surface area, while at the same time maximizing the surface area of the hot junction, which provides redundancy: partial destruction, such as a claw, will be less likely to compromise the performance of the thermocouple.

Consequently, the invention allows to measure temperatures in confined parts of aeronautical equipment, in particular engines, where the measurement must be as least intrusive as possible, because it is necessary to minimize the aerodynamic disturbance of the flow.

### PRESENTATION OF THE FIGURES

Other features, aims and advantages of the invention will emerge from the description which follows, which is purely illustrative and not limiting, and which must be read with reference to the appended drawings in which:

FIG. 1 illustrates a side view of a thermocouple according to a first embodiment of the invention;

FIG. 2 and FIG. 3 illustrate a side view of a thermocouple according to a second embodiment of the invention;

FIG. 4 illustrates a side view of a thermocouple according to a third embodiment of the invention with identified dimensions;

FIG. 5 illustrates a side view of a thermocouple according to a fourth embodiment of the invention;

FIG. 6 illustrates a side view of a thermocouple according to a fifth embodiment of the invention;

FIG. 7 illustrates steps of a method for manufacturing a thermocouple according to one embodiment of the invention;

FIG. 8 illustrates steps of a method for manufacturing a thermocouple according to one embodiment of the invention;

FIG. 9, FIG. 10, FIG. 11 and FIG. 12 illustrate a thermocouple according to the invention with connection terminals in various configurations;

FIG. 13 illustrates the integration of a thermocouple according to the invention.

In all the figures, similar elements bear identical references.

### DETAILED DESCRIPTION

### General Structure of a Thermocouple According to the Invention

FIGS. 1 to 6 each illustrate a thermocouple according to different embodiments of the invention.

The thermocouple according to the invention comprises a first arm 1 and a second arm 2 arranged on a substrate 3, the second arm 2 at least partially overlapping the first arm 1.

The first arm 1 and the second arm 2 are made of different materials and the substrate 3 is made of an electrically insulating material.

The substrate 3 must be electrically insulating in order to avoid a short circuit which would disrupt the measurement. It may be a thermal barrier coating made of yttriated zirconia, yttrium or ytterbium mono- or disilicate, alumina, oxide layer of a superalloy, or any other dielectric.

The substrate 3 comprises an upper face 31 and a lower face 32 which are opposite and parallel to each other.

The substrate is intended to be arranged on a support such as an aeronautical part or an electronic circuit.

The thermocouple can indeed be used to measure the temperature prevailing in turbomachine blades. In this case, the substrate 3 is arranged on a support 200 which is a turbomachine blade which is made of metal and therefore electrically conductive. The substrate 3 can either be added and constitute an overlayer of a few tens of microns or be formed by the direct oxidation of the surface of the blade 200.

Alternatively, the thermocouple can be used to measure the temperature in an electronic circuit at a very precise point on the component. The support 200 then being formed by a surface of a semiconductor or a Rogers type dielectric.

Thus, as understood, the substrate 3 can be in several types of shapes which depend on the application made of the thermocouple and in particular the support on which it is arranged.

The first and second arms 1, 2 are advantageously made up of thin electrically conductive tracks deposited on the substrate 3.

For example, the first arm 1/second arm 2 pair is selected from the following group Pt/Pt—Rh; Ni—Cr/Ni—Al; Cu/Cu—Ni; Fe/Cu—Ni; Ni—Cr/Cu—Ni; Ni—Cr—Si/Ni—Si.

More generally, the person skilled in the art will know how to choose the appropriate combination of materials among those known in the state of the art, in order to meet the need for temperature measurement, depending on the temperature range and the desired precision. The first arm 1 comprises a first connection terminal 11 and the second arm 2 comprises a second connection terminal 21 which are opposite above the substrate 3.

It is to the connection terminals 11, 22 that connection elements (wires for example) C1, C2 are connected to recover the measurement, these wires here connect the thermocouple to contact pads (not visible here). These connection elements C1, C2 are in particular glued to the connection terminals 11, 21 by means of an adhesive 100 (silver-based conductive paste type) or by soldering. The objective is to provide a conductive element to ensure such a connection.

The first arm 1 comprises a first horizontal part 12 arranged and in contact on the upper face 31 of the substrate 3 and the first connection terminal 11 which is here preferably a perpendicular vertical part which extends from an external end 14 of the first horizontal part 12. The first arm 1 comprises an internal end 13 which opens towards the inside of the upper face 31 of the substrate 3 and the external end 14 from which the first connection terminal 11 extends.

The second arm 2 has a structure identical to that of the first arm 1 but is arranged on the substrate 3 differently from the first arm 1. As such, the second arm 2 comprises a second horizontal part 22 in contact with the first horizontal part of the first arm 1. In particular, the second horizontal part 22 of the second arm 2 is in contact with the first horizontal part 12 of the first arm 1, the horizontal parts overlapping either partially or completely. The second connection terminal 21 here also which extends vertically and perpendicularly from the horizontal part 22 is arranged on the upper face 31 of the substrate 3 and the second horizontal part 22 extends from the second connection terminal 21 towards the inside of the face of the first horizontal part 12.

The first and second connection terminals are described here as extending perpendicularly from each first and second horizontal parts but this is not mandatory and depends on the type of thermocouple connection.

The zone of contact between the first arm 1 and the second arm 2 allows to define a “hot junction” 6. In particular, it is the zone of contact between the first horizontal part 12 of the first arm 1 and the second horizontal part 22 of the second arm 2 which defines the hot junction.

The cold junction is located at a distance from the thermocouple structure and is defined by the connection elements C1, C2, the measurement being made between the two connection elements C1, C2.

The second arm 2 comprises an internal end 23 which opens towards the inside of the upper face 31 of the substrate 3 on the first horizontal part 12 of the first arm 1 and an external end 24 from which the second connection terminal 21 extends.

Thus, the entire first horizontal part 12 of the first arm 1 is in contact with the upper face 31 of the substrate 3 while for the second arm 2 only the second connection terminal 21 is in contact with the upper face 31 of the substrate 3.

The first and second arms 1, 2 are thus preferably both L-shaped arranged relative to each other such that their horizontal part 12, 22 overlap at least partially depending on the dimension to be given to the hot junction.

Various embodiments resulting from the general presentation thus made are described below.

### First Embodiment

FIG. 1 illustrates a side view of a thermocouple according to a first embodiment of the invention.

According to this first embodiment, the first arm 1 and the second arm 2 completely overlap. In particular, the first horizontal part 12 of the first arm 1 completely overlaps the second horizontal part 22 of the second arm 2. Thus, the entire thermocouple including the contact points and part of the wires are exposed to the same thermal field which is considered homogeneous. The cold solder is carried further and the two arms can touch each other on several surfaces.

An application here is to arrange the thermocouple on a blade 200 of a turbomachine, the hot junction being maximized and the cold junction is distant.

The hot junction is therefore on the blade at the location of the thermal field and the cold junction is carried further outside the thermal field and can move away from the field to the ends of the blade. Maximizing the hot junction allows to guarantee the measurement of the temperature in this thermal field considered homogeneous, and to be as precise as possible when taking measurements in the thermal field in question.

### Second Embodiment

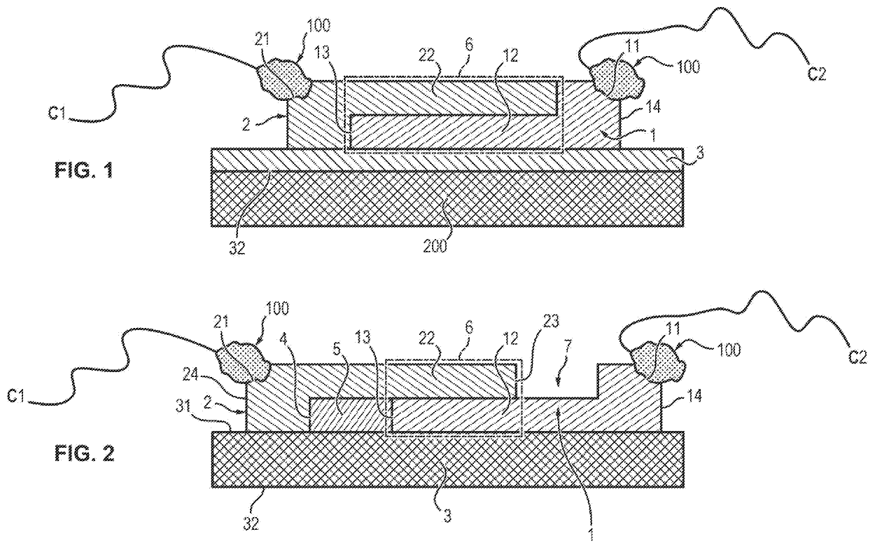

FIG. 2 illustrates a side view of a thermocouple according to a second embodiment of the invention.

According to this second embodiment, the first arm 1 and the second arm 2 partially overlap so as to define a first free space 4 between the substrate 3, the second arm 2 and the first arm 1. In particular, the second horizontal part 22 of the second arm 2 partially overlaps the first horizontal part 12 of the first arm 1.

The first free space 4 allows the independent electrical connection of each arm and allows to define the “hot junction” zone 6 of the thermocouple.

The second arm 2 thus comprises a second horizontal part 22 here suspended above the upper face 31 of the substrate 3 but in partial contact with the first arm 1.

The first free space 4 is defined by the second connection terminal 21 and the first and second horizontal parts 12, 22 of the arms 1, 2.

The overlapping zone of the arms 1, 2 constitute the hot junction 6 and is marked in FIG. 2 by a central rectangle: this is the overlapping zone of the arms 1, 2.

Advantageously, the first free space 4 is filled with a dielectric material 5 which is electrically insulating in the desired operating range of the thermocouple. As can be seen, the dielectric material 5 is arranged below the second arm 2 in order to ensure the electrical separation of the hot junction.

Providing such a first free space 4 allows to electrically insulate the arms 1, 2. Filling it with dielectric 5 increases this insulation. Furthermore, this avoids leaving an empty “hole” in the structure of the thermocouple that is detrimental to its mechanical stability. The second arm 2 is therefore not in suspension. Additionally, a vacuum can cause an accumulation of water or other annoying elements, which for example would corrode the arms, or cause an unwanted short circuit between the arms.

According to this second embodiment and by construction, the first horizontal part 12 of first arm 1 and the second horizontal part 22 of the second arm 2 partially overlap above the substrate 3 so as to leave a second free space 7 between the two arms 1, 2.

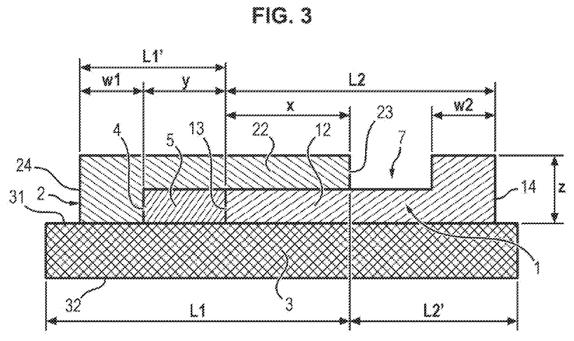

FIG. 3 illustrates the thermocouple according to the second embodiment with different dimensions. The length x corresponds to the length of the hot junction seen from the side. This length x is at least of the order of a few tens of nanometers when the thermocouple is arranged on an electronic circuit or at least of the order of a micron when the thermocouple is arranged on a turbomachine blade. In the context of microelectronics, components such as a transistor can reach a very small dimension of around ten nm, in this case x is therefore of the order of the size of a transistor on an electric circuit. On the other hand, x can be larger if it is desired to probe a temperature under a set of transistors which form an electronic chip.

When it comes to probing the temperature at a location of a blade of the turbomachine, x is at least of the order of the size of the metal grains of the superalloy materials forming the blade. Thus, x is typically greater than 1 μm.

The widths w1, w2 of the first and second connection terminals 11, 21 must be minimized while being sufficiently wide to allow a good connection by gluing or soldering the connection wires. Such widths w1, w2 are to be optimized with the width y of the first free space 4 filled with dielectric. When the first and second arms 1, 2 are thin conductive tracks (that is to say a few nanometers), w1, w2 can be of the order of a few tens of nanometers (in the case of depositions known in the semiconductor industry, such as lithographic depositions) or of the order of a few tens of micrometers in the case of depositions based on printing methods such as screen printing, inkjet, aerosol jet, micro extrusion . . . .

In the case of cable soldering by wires (or wire-bonding) using a wire or soldering using glue, the connection terminals can be of the order of a few tens of μm such as the diameter of the connection wires which will be soldered or glued on top. For example, a platinum wire may be of the order of 60 μm. In the case where the step of gluing or soldering a wire is avoided and the connectors of the electronic circuit are joined, w1 and w2 in this embodiment are proportional to z that is to say 2*z, 3*z, etc.

The lengths L1, L2 (taken from the side) of the first and second arms 1, 2 are such that they provide sufficient contact to establish the hot junction but short enough to compact the assembly or long enough to add the interconnection points quite far depending on the integration of the thermocouple.

The lengths L1′=L1−x and L₂′=L2−x can go up to several millimeters in length (from 1 mm to reach the longest dimension of the part which can preferably be a blade (a turbomachine blade can go up to 600 mm), in order to add the connection point away from the hot junction.

The height z of the first connection terminal 11 must be minimal to avoid disruption of the aerodynamic flow or quite simply to compact the thermocouple, especially if it is part of a microelectronic circuit. The height z can vary between a few tens of nanometers in the case of applications in microelectronics (manufacture then by lithography and PVD, CVD deposition) and a few μm or tens of microns for aeronautical applications using printing methods mentioned above.

Indeed, the out-of-plane thickness of the substrate 3 for applications in aeronautics, particularly when the thermocouple is arranged on a blade of a turbomachine, must be less than 50 μm in order not to disturb the aerodynamic flow.

### Third Embodiment

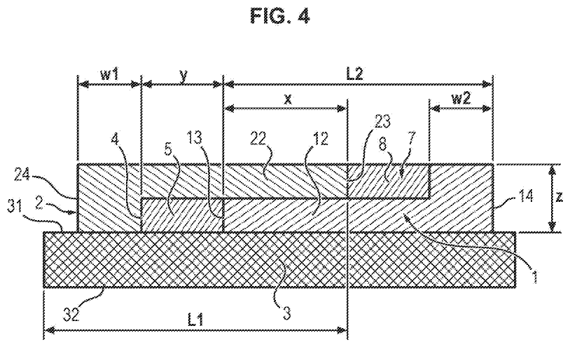

FIG. 4 illustrates a thermocouple according to a third embodiment of the invention. In addition to the features of the second embodiment, the second free space 7 is filled with a dielectric material 8 identical to that which fills the first free space 4. The fact of filling the two free spaces defined by the arms 1, 2 allows to have good mechanical stability of the structure: the structure is compact and made in one piece and the structure of the arm 2 is not suspended. Additionally, a vacuum could cause an accumulation of water or other disturbing elements, which for example would corrode the arms or cause an unwanted short circuit between the arms. Filling the space 7 also allows to “smooth” the structure and avoid, for example, the snagging of the aerodynamic flow and the creation of vortices which degrade the performance of aeronautical equipment, in the context of an aeronautical application.

### Fourth Embodiment

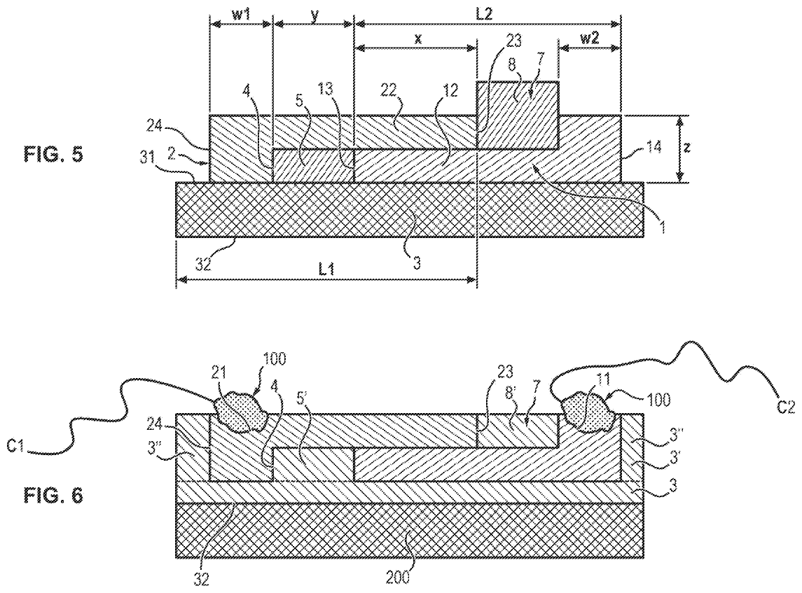

FIG. 5 illustrates a thermocouple according to a fourth embodiment which takes up all the features of the second embodiment while having however the dielectric material 8 which fills the second free space 7 which exceeds in height seen from the side of the thickness of the arms 1, 2. Such exceeding allows to prevent the surrounding glue 9 from spreading, the dielectric material acting as a barrier which could cause the two arms to connect together, the glue being conductive. Indeed, when an operator applies the glue, he risks spreading it too much and thus short-circuiting the two arms. The material 8 that exceeds prevents this.

### Fifth Embodiment

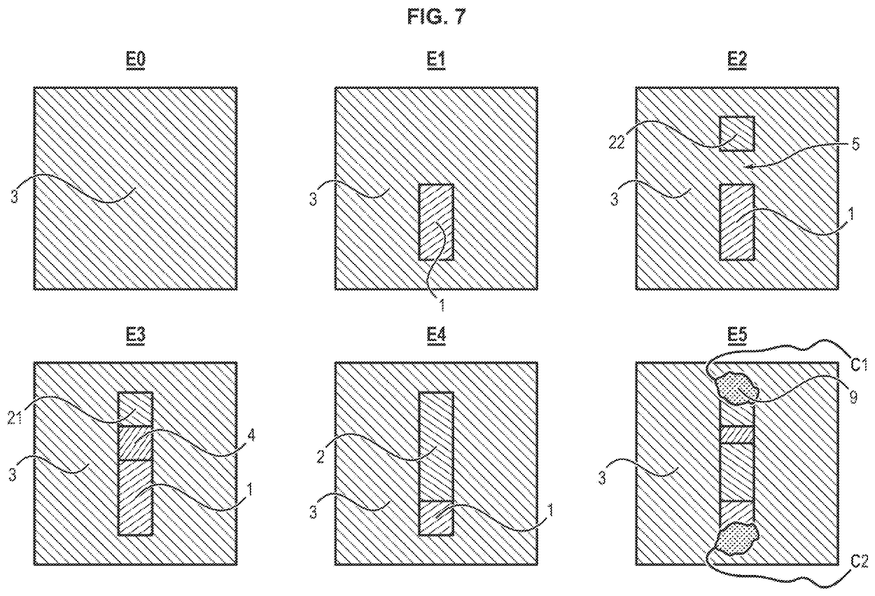

FIG. 6 illustrates a thermocouple according to a fifth embodiment which is similar to the second embodiment and for which the first and second arms 11, 21 are embedded in an insulating material referenced by 3′ in FIG. 6 formed of the substrate 3, dielectric materials 5′, 8′ arranged in free spaces 4, 7 as well as by lateral parts 3″ which surround the arms 1, 2 extending from the substrate 3.

According to this embodiment, the thermocouple can therefore be embedded in the oxide layer or thermal barrier of the support such as a blade or directly in the dielectric of an electronic circuit.

Furthermore, according to this embodiment, the main advantage lies in the ease of integration of the thermocouple within the oxide layer or thermal barrier. This makes the assembly compact, thin, miniature and non-intrusive. This also allows to reduce wiring, the mass of components in order to improve the performance of an electronic card and to carry out monitoring in the case of a turbomachine blade.

### Manufacturing Methods

A method for manufacturing a thermocouple according to the first, second, third and fourth embodiments of the invention is now described in relation to the FIG. 7.

In a preliminary step (step E0) a substrate is taken and the upper face 31 which will receive the arms 1, 2 of the thermocouple is prepared. Such a step is implemented by known techniques such as plasma activation, cleaning, polishing, etc. In all cases, it is ensured that the surface is electrically insulating.

Then, the first arm 1 is deposited (step E1) by well-known deposition sequences. This may involve a lithography or functional ink printing method, followed by sintering to remove the organic components of the ink, solder the metal particles of the ink together and thus form a continuous conductive track. The first arm 1 is deposited up to a desired height on the upper face 31 of the substrate 2.

Then, part of the second arm 2 is deposited (step E2). This is the second connection terminal 21. This terminal 21 is deposited up to the desired height on the upper face 31 of the substrate, that is to say up to the same height as the first arm 1. The same deposition technique as the first arm 1 is used.

Depending on whether the thermocouple is manufactured with or without free space (first embodiment vs second or third embodiment) the first free space 4 is provided and thus the dielectric material 5 is then deposited between the second connection terminal 21 and the first arm 2 in the first free space 4 (step E3). The dielectric material 5 is deposited up to the same height as the second connection terminal 21 on the one hand and up to the same height as the first arm 1.

Then, the horizontal part 22 of the second arm 2 is deposited in order to make the hot junction while leaving a free space 7 between the first connection terminal 11 and the second arm 2 (step E4).

Finally the connection wires C1, C2 are connected to the connection terminals 11, 21 (step E5). Such a connection, for example, implemented by means of glue 9 (silver-based conductive paste type) or by soldering.

Alternatively, the dielectric material 5 in the first free space can be deposited before the second arm 2. The advantage of first depositing the dielectric material allows to use a resin which withstands the high temperatures necessary to deposit the second arm 2 by sintering for example.

To deposit the different elements, several techniques are possible.

The methods called “printing” deposition methods based on functional inks of metal and/or dielectric materials by methods such as inkjet, aerosol jet, screen printing, microextrusion (or dispensing). Sintering at a higher temperature can also be used (at least the operating temperature), which ensures the soldering of the metal particles together and the formation of a continuous conductive track.

Other methods such as thermal spray can be used. This method consists of projecting hot material which, upon impacting the substrate, instantly cools and solidifies. Masks are necessary to define the desired structures on the substrate.

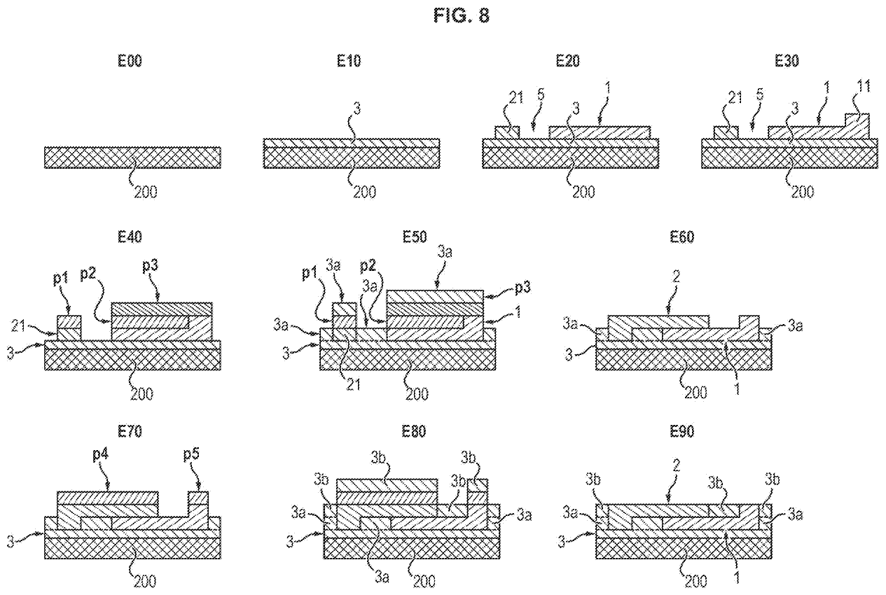

A method for manufacturing a thermocouple according to the fifth embodiment of the invention is now described in relation to the FIG. 8.

A support is provided, for example the blade 200 of a turbomachine (step E00).

The substrate 3 made of electrically insulating material is deposited on the support 200 (step 10).

Then the depositions of the first arm 1 then of a part of the second arm 2 forming the connection terminal 21 (step E20) is carried out. These depositions as well as the following ones are implemented by sequences of well-known depositions. This may involve a lithography method or the printing of functional inks, followed by sintering to remove the organic components of the ink, solder the metal particles of the ink together and thus form a continuous track. The first arm 1 and this part of the second arm 2 are deposited up to a desired height on the upper face 31 of the substrate 3.

The connection terminal 11 of the first arm 1 is then deposited (step E30) at the external end of the first arm 1.

Then the deposition (step E40) of temporary layers P1, P2, P3 on the first arm 1: a first temporary layer P1 on the connection terminal 21 of the second arm 2, a second temporary layer P2 on the horizontal part 12 of the first arm 1 and a third temporary layer P3 on the connection terminal 11 of the first arm 1 and on the layer P2, is carried out. These temporary layers P1, P2, P3 are in particular made of resin and require drying or baking.

A first masking step consisting of depositing an insulating material 3a identical to that of the substrate 3 on the assembly formed after the deposition of the three temporary layers P1, P2, P3 first temporary layer P1 overlapping the connection terminal 21 of the second arm 2 and on the third temporary layer P3 (step E50). The temporary layers allow to protect the elements which form the arms 1, 2.

The excess above the arms is removed to leave insulating material only in the zones above the substrate 3 deposited in step E10 and the deposited (step E60) horizontal part 22 of the second arm 2.

A second masking step is then implemented and consists of depositing fourth and fifth temporary layers P4, P5 on the parts of the arms which are not intended to be overlapped with insulating material, this is the second arm 2 and the connection terminal 11 of the first arm 1.

Layers of insulating material 3b identical to that of the material 3, 3a, 3b are then deposited on the assembly formed at the end of step E70 (step E80), then the masking as well as the excess of the insulating material is removed (step 90). Then the thermocouple embedded in the insulating material is obtained.

Then, all that remains is to connect the connection terminals to the connection terminals 11, 21 of each of the arms 1, 2.

### Variants and Type of Connections

Connection terminals from which connection wires C1, C2 extend were previously described.

In particular, it was described that the connection terminals are perpendicular to the first and second horizontal parts of the first and second arms 1, 2.

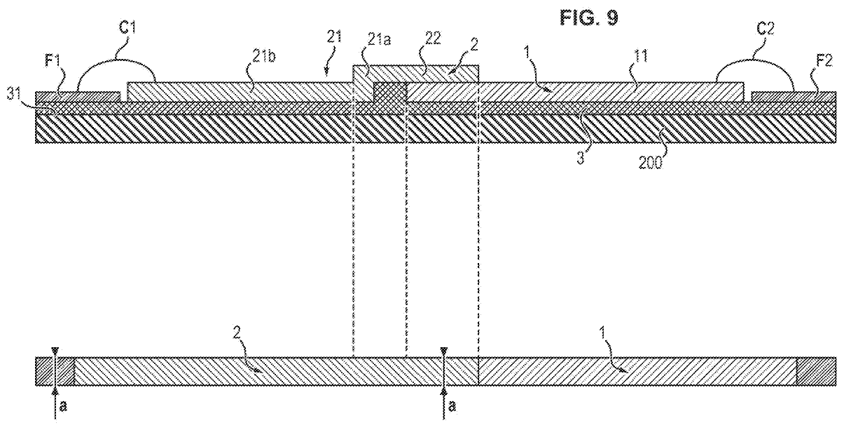

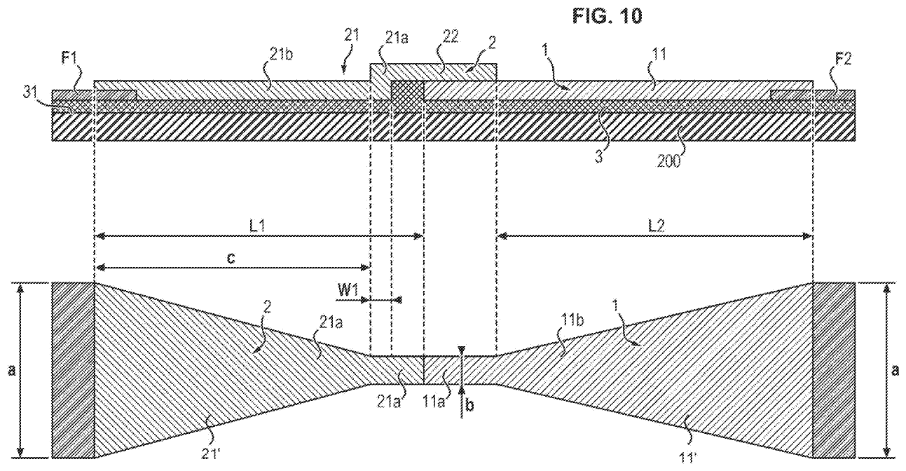

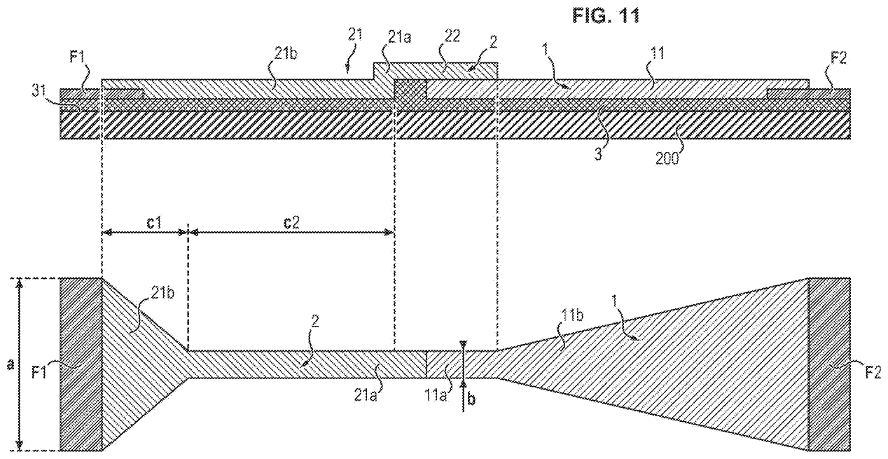

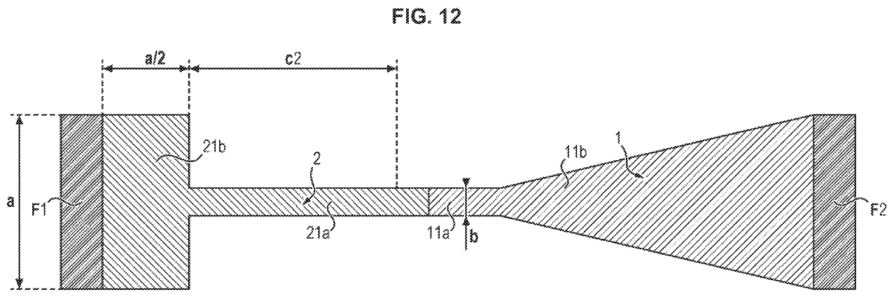

As visible in FIG. 9 in side view, and in FIG. 9 in top view, the second connection terminal 21 consists of two parts, a part 21a perpendicular to the second horizontal part 22 and a third horizontal part 21b extending from the second connection terminal parallel to the upper surface 31 of the substrate 3. On the other hand, here the first arm comprises a connection terminal 11 which is horizontal and which is in the extension of the first horizontal part.

Thus, the connection terminals extend from the first and second horizontal parts of each arm 1, 2 to move away from the hot junction and get as close as possible to the cold solder. Connection wires C1, C2 connect the arms to the pads F1, F2 of the cold solder. The pads F1, F2 have the same width denoted a (in top view) as the arms 1, 2.

Alternatively, as visible in FIG. 10, the connection terminals also extend over the upper surface of the substrate 3 but here there are no connection wires, the ends of the connection terminals come into contact with the pads F1, F2 of the cold solder.

Also as is visible in FIG. 10 in top view, the arms flare towards the connection pads F1, F2 of the cold solder and each comprise first a rectilinear part 11, 21 then a part which flares 11′, 21′. In particular, the first and second arms flare over a distance denoted c from parts 11a, 21a. The width of the pads F1, F2 is equal to the width of the most flared part of the arms 1, 2.

According to yet another variant illustrated in FIG. 11, the connection terminals are first straight and then flare towards the cold solder pads.

Another variant illustrated in FIG. 12 shows that an arm 2 comprises a connection terminal consisting of a rectilinear part 21 then ends with a rectangular part 21′ to connect to a connection pad.

It is understood that depending on the type of connection, the arms can be of different shapes.

The shape of the arms is dictated by the thermocouple connection environment. Sometimes this involves avoiding components present in the thermocouple integration environment.

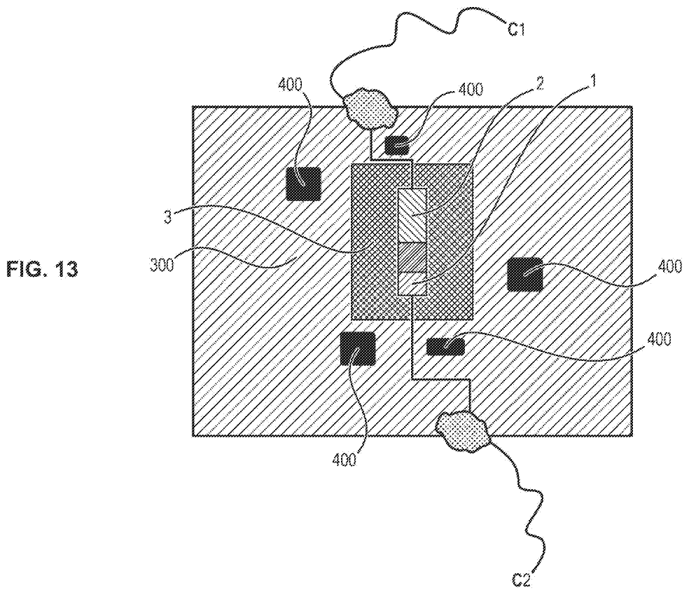

FIG. 13 illustrates the integration of a thermocouple. It is seen in this figure that the two arms 1, 2 travel along the desired path on a board 300. It is in particular the connection terminals which are formed to travel on the board while avoiding components 400 already present on the board (materialized by rectangles).

1-13. (canceled)

14. A thermocouple comprising:
a substrate comprising an upper surface;
a first arm comprising a first horizontal part and a first connection terminal;
a second arm comprising a second horizontal part and a second connection terminal;
the first arm being arranged on the upper surface of the substrate, the second arm being arranged on the first arm such that the second horizontal part partially overlaps the first horizontal part, so as to define a first free space between the substrate, the first arm and the second arm, and such that the second connection terminal is in contact with the upper part of the substrate, a hot junction of the thermocouple being defined by the zone of contact between the first arm and the second arm.

15. The thermocouple according to claim 14, comprising a dielectric material arranged in the first free space.

16. The thermocouple according to claim 14, wherein the first arm comprises an internal end and an external end from which the first connection terminal extends from the substrate.

17. The thermocouple according to claim 14, wherein the second arm comprises an internal end and an external end from which the second connection terminal extends.

18. The thermocouple according to claim 14, wherein the second arm partially overlaps the first arm so as to define a second free space between the first connection terminal and the internal end of the second arm.

19. The thermocouple according to claim 18, comprising a dielectric material arranged in the second free space.

20. The thermocouple according to claim 15, wherein the dielectric material is such that it is insulating in a temperature operating range of said thermocouple.

21. The thermocouple according to claim 15, comprising a dielectric material arranged in the second free space, wherein the dielectric material is such that it is insulating in a temperature operating range of said thermocouple.

22. The thermocouple according to claim 18, wherein the second free space has a larger volume than the volume of the first free space.

23. The thermocouple according to claim 14, wherein the substrate is electrically insulating.

24. The thermocouple according to claim 23, wherein the substrate is selected from the following group: a thermal barrier coating made of yttria zirconia, yttrium or ytterbium mono- or disilicate, alumina, oxide layer of a superalloy, or any other dielectric.

25. The thermocouple according to claim 14, wherein the first arm and the second arm are enveloped in an insulating material of the same material as the substrate.

26. A method for manufacturing a thermocouple according to claim 14, comprising the following steps:
depositing the first arm on a substrate;
depositing the second connection terminal of the second arm on the substrate so as to leave a first free space between the substrate, the first arm and the second arm;
depositing a horizontal part of the second arm from the second connection terminal towards the inside of the substrate so as to at least partially overlap the first arm to form a hot junction of the thermocouple.

27. A device for measuring the temperature of a turbomachine blade, comprising a thermocouple according to claim 14, the substrate being arranged on the blade.

28. A device for measuring the temperature of a determined zone of an electronic circuit, comprising a thermocouple according to claim 14, the thermocouple being arranged in the determined zone such that the hot junction is arranged on the determined zone.
